(19) United States
(12) Patent Application Publication
(10) Pub. No.: US 2010/0009507 A1
(43) Pub. Date: Jan. 14, 2010

(54) METHOD OF CONSTRUCTING CMOS DEVICE TUBS

(76) Inventor: Thomas J. Krutsick, Fleetwood, PA (US)

Correspondence Address: WILLIAMS, MORGAN & AMERSON, 10333 RICHMOND, SUITE 1100, HOUSTON, TX, 77042, US

(21) Appl. No.: 12/170,712

(22) Filed: Jul. 10, 2008

(51) Int. Cl. H01L 21/8228

(52) U.S. Cl. 438/322; 257/E21.611

(57) ABSTRACT

The present invention provides a method of fabricating an integrated circuit comprising at least one bipolar transistor and at least one field effect transistor. The method includes implanting a dopant species of a first type in a semiconductor layer that is doped with a dopant of a second type opposite the first type to form at least one sinker that contacts at least one collector of said at least one bipolar transistor. The method also includes applying heat to cause the dopant species to diffuse outwards to form at least one doped extension of said at least one sinker and forming said at least one field effect transistor in the doped extension.

### BACKGROUND OF THE INVENTION

1. Field of the Invention

This invention relates generally to semiconductor fabrication and, more particularly, to constructing CMOS device tubs.

2. Description of the Related Art

The transistor is one of the fundamental building blocks of conventional integrated circuits including processors, memory elements, application-specific integrated circuits (ASICs), and the like. Two of the most commonly used technologies are bipolar transistor technologies and metal oxide semiconductor field effect transistor (MOSFETs) technologies that are used to form transistors such as Complementary Metal Oxide Semiconductor (CMOS) transistors. A typical CMOS transistor includes source and drain regions that are separated by a channel region. When the appropriate signal (usually a voltage of a specified magnitude) is applied to a conducting gate region in the transistor, the transistor turns on and allows current to flow from the source region, through the channel region, and into the drain region. Numerous different technologies can be used to form transistors.

Bipolar transistors include an emitter region, a base region, and a collector region that are alternately doped with either n-type or p-type material. For example, an n-p-n bipolar transistor includes an emitter region that is doped with n-type material, a base region that is doped with p-type material, and a collector region that is doped with n-type material. For another example, a p-n-p bipolar transistor includes an emitter region that is doped with p-type material, a base region that is doped with n-type material, and a collector region that is doped with p-type material. The structure and operating parameters of a bipolar transistor are therefore determined, at least in part, by the dopant profiles that result from the specific processes that are used to dope the emitter, base, and/or collector regions.

FIGS. 1A, 1B, 1C, 1D, and 1E conceptually illustrate a conventional technique for forming an n-p-n bipolar transistor. Initially, as shown in FIG. 1A, an SOI substrate 100 is used as the starting material for the present invention. As depicted in FIG. 1A, the SOI substrate 100 is comprised of a bulk substrate 100a, a buried insulation layer 100b and an active layer 100c. Typically the bulk silicon 100a is comprised of silicon, the buried insulation layer 100b is comprised of silicon dioxide (a so-called buried oxide or “BOX” layer), and the active layer 100c is comprised of silicon (doped or undoped). Such SOI structures may be readily obtained from a variety of commercially known sources. Typically, the buried insulation layer 100b will be relatively thick, e.g., on the order of approximately 500-1000 microns, and the active layer 100c may have an initial thickness of approximately 1-5 microns.

Thereafter, as indicated in FIG. 1A, a doped buried layer is formed by implanting or depositing a dopant species into the active layer 100c and a doped layer of silicon 105 is formed above the active layer 100c. For example, a portion of the silicon 105 can be doped with an N-type dopant material, e.g., phosphorous, arsenic, such that it has a resistivity of approximately 2-15 ohm-cm which corresponds to a dopant concentration of approximately 2×10¹⁴ to 5×10¹⁵ ions/cm³. The layer of silicon 105 is a layer of epitaxial (epi) silicon that is deposited in an epi reactor. In this situation, the layer of epitaxial silicon 105 may be doped by introducing dopant materials into an epi reactor during the process used to form the layer 105. However, the dopant material may also be introduced into the layer of silicon 105 by performing an ion implant process after the layer of silicon 105 is formed. The layer of silicon 105 is relatively thick. In one illustrative embodiment, the layer of silicon 105 has a thickness that ranges from approximately 1-30 microns, depending on the particular application.

Referring now to FIG. 1B, the distribution of dopant atoms within the layer of silicon 105 may not be uniform throughout its depth. For example, the layer 105 may include a relatively higher concentration region near the active layer 100c. The higher concentration region forms a sub-collector (or buried layer) 120 for the bipolar transistor. For example, in high-voltage applications that have a relatively thick epitaxial layer, the dopant species in the buried doped layer that is formed in the active layer 100c diffuses up (and down) to form the sub-collector or buried layer 120. Although the active layer 100c and the collector 120 are depicted as separate entities in FIG. 1B, in practice diffusion of the dopant blurs the distinction between these layers so that the active layer 100c and the portion of the collector 120 may be indistinguishable from each other. For an n-p-n bipolar transistor, the dopant implantation process 115 may be used to implant an n-type dopant into the silicon layer 105 to form the sub-collector 120. The dopant concentration of the sub-collector 120 is approximately 10¹⁸ to 10²⁰ atoms/cm³. The sub-collector 120 is typically located approximately 1-20 microns below the top surface of the doped layer 105 and extends approximately to the substrate 100.

Referring now to FIG. 1C, a thermal oxidation process can be used to grow selected portions of the silicon dioxide layer 110. In the illustrated embodiment, the thermal oxidation process is used to grow portions of a pad oxide layer 125(1-2) and a masking layer (not shown) is used to prevent regions between these portions from growing. Thermal oxidation and the consequent growth of the pad oxide layer 125 consume a portion of the doped region 120. Persons of ordinary skill in the art should appreciate that FIG. 1C is intended to be illustrative and is not drawn to scale. Thus, the relative thicknesses of the elements shown in FIG. 1C may not correspond to the values used in actual devices.

Referring now to FIG. 1D, a base region 130 for the n-p-n bipolar transistor is typically formed by implanting a p-type dopant in a portion of the silicon layer 105, as indicated by the arrows 135. The dopant concentration in the base region 130 is typically approximately 10¹⁷-10¹⁹ atoms/cm³ and the base region extends to a depth of up to a few thousand angstroms. Although the base region 130 shown in FIG. 1D is precisely lined up with the top surface of the silicon layer 105, other base regions 130 do not necessarily have to be lined up in this manner. For example, the base region 130 can be completely within the bounds of the oxide layer 125 so that a portion of the silicon layer 105 extends above the lower boundary of the oxide layer 125 or the base region 130 can diffuse into a portion of the silicon layer 105 below the lower boundary of the oxide layer 125.

A sinker 140 is also formed by implanting an n-type dopant species into a portion of the layer 105. In the process shown in FIG. 1D, the sinker 140 is formed before the base 130 during the same temperature treatments that form the oxide 125. The dopant species for the sinker 140 is implanted and diffused with heat treatments to a depth sufficient to contact the collector 120. The oxide layer 125 has been thinned in the region over the sinker 140 so that a doped and species implanted through the pad oxide layer 125 (or an opening therein) using an energy that is selected to deposit the dopant atoms throughout the region between the surface of the layer 105 and the collector 120 as indicated by the arrows 145.

Referring now to FIG. 1E, an emitter region including an n-p junction 150 for the n-p-n bipolar transistor is formed in the base region 130 using a material that is doped with an N-type dopant species. Typical dopant concentrations of the emitter regions 150 are in the range approximately 10¹⁹-10²¹ atoms/cm³. Contacts 155 to the base region 130, the junction 150, and the sinker 140 are then formed using conductive material such as polysilicon. The contacts 155 typically pass through the oxide layer 125. The bipolar transistor also typically includes one or more passivation layers that are formed over the pad oxide layer 125 and other elements of the bipolar transistor (the passivation layers are not shown in FIG. 1E).

Conventional CMOS transistors include a source region, a drain region, and a gate electrode formed in a semiconductor material. The gate electrode is formed of a conductive material and overlays a channel region that is between the source and drain regions. The channel region is doped with one type of dopant and the source and drain region are doped with the opposite type of dopant.

FIG. 2 depicts an example of a conventional CMOS transistor 210 fabricated on an illustrative substrate 211 comprised of, for example, silicon. The transistor 210 is comprised of a gate insulation layer 214, a gate electrode 216, sidewall spacers 219, and source/drain regions 218. The gate electrode 216 has a critical dimension 216A that approximately corresponds to the gate length of the transistor 210. A plurality of trench isolation regions 217 are formed in the substrate 211 to electrically isolate the transistor 210 from other transistors (not shown) or structures. Although not depicted in FIG. 2, in some cases the trench isolation regions 217 may extend to a BOX layer, which is not shown in FIG. 2. In this case, the trench isolation regions 217 would be more separated from the source/drain 218. Alternatively, the trench isolation regions 217 could be used to isolate a group of devices and a standard channels top isolation guard rings could be used internally to isolate devices. Also depicted in FIG. 2 is a plurality of conductive contacts 220 formed in a layer of insulating material 221. The conductive contacts 220 provide electrical connection to the source/drain regions 218. As constructed, the transistor 210 defines a channel region 212 in the substrate 211 beneath the gate insulating layer 214. The transistor 210 further comprises a plurality of metal silicide regions 213 formed above the gate electrode 216 and source/drain regions 218.

The metal silicide regions 213 may be formed by depositing a layer of refractory metal (not shown), e.g., nickel, cobalt, titanium, platinum, erbium, tantalum, etc., above the source/drain regions 218, the sidewall spacers 219 and the gate electrode 216. Thereafter, a two-step heating process may be performed to convert the portions of the layer of refractory metal in contact with the gate electrode 216 and the source/drain regions 218 into a metal silicide, e.g., nickel silicide, cobalt silicide, etc. Such silicide regions 213 are formed for a variety of purposes, e.g., to reduce the contact resistance for the source/drain regions 218 and gate electrode 216. The metal silicide regions 213 may, at least in some cases, assist in increasing device performance in that they tend to reduce various resistances encountered in operating the transistor 210.

Many integrated circuit designs include both bipolar transistors and CMOS transistors. For example, an ASIC may be built using primarily bipolar devices with a small number of additional CMOS transistors to act as switches or other logical elements of the circuit. However, in some ways these two technologies are incompatible. For example, since bipolar transistors include a collector that is formed below the emitter and/or base regions, bipolar transistors are formed in semiconductor layers that are much thicker than the semiconductor layers that are used to support a CMOS transistor. The thickness of the semiconductor layer generally needs to remain the same throughout the integrated circuit and so the CMOS devices must be formed in a thicker-than-optimal semiconductor layer. To address this mismatch, circuits that include both bipolar transistors and CMOS transistors include additional fabrication steps. For example, additional masking and/or implantation steps are typically used to form a relatively shallow well or a tub in the semiconductor layer and then the CMOS devices are formed within the wells or tubs.

FIG. 3 illustrates a conventional integrated circuit 300 that includes a bipolar transistor 305 and a CMOS transistor 310 that are formed in a semiconductor layer 315 above a substrate 320. The bipolar transistor 305 is formed using the conventional bipolar technologies described herein and includes an emitter 323, a base region 325, a collector 330, and a sinker 335. The CMOS transistor 310 includes a source 340, a drain 345, and a gate 350 and is formed in a tub 355. In some cases, a tub tie (not shown) can also be formed. The tub 355 is formed in the semiconductor layer 315 by implanting a dopant species, e.g. through a patterned masking layer (not shown) that is used to define the boundaries of the tub 355. The CMOS transistor 310 is then formed in the tub 355 according to the conventional process described herein.

The bipolar transistor 305 and the CMOS transistor 310 should be constructed so that they operate independently. For example, voltages and/or currents applied to or generated by one of the transistors 305, 310 should not significantly influence operation of the other transistor. Consequently, the bipolar transistor 305 is physically and electrically isolated from the CMOS transistor 310 by a trench 360. The trench 360 can be formed using conventional etching and/or deposition processes. For example, the trench 360 may be formed by etching a portion of the semiconductor layer 315 and then using various deposition processes to deposit one or more dielectric layers (not shown) and a polysilicon fill (not shown).

### SUMMARY

The disclosed subject matter is directed to addressing the effects of one or more of the problems set forth above. The following presents a simplified summary of the disclosed subject matter in order to provide a basic understanding of some aspects of the disclosed subject matter. This summary is not an exhaustive overview of the disclosed subject matter. It is not intended to identify key or critical elements of the disclosed subject matter or to delineate the scope of the disclosed subject matter. Its sole purpose is to present some concepts in a simplified form as a prelude to the more detailed description that is discussed later.

In one embodiment, a method is provided for fabricating an integrated circuit comprising at least one bipolar transistor and at least one field effect transistor. The method includes implanting a dopant species of a first type in a semiconductor layer that is doped with a dopant of a second type opposite the first type to form at least one sinker that contacts at least one collector of said at least one bipolar transistor. The method also includes applying heat to cause the dopant species to diffuse outwards to form at least one doped extension of said at least one sinker and forming said at least one field effect transistor in the doped extension.

### BRIEF DESCRIPTION OF THE DRAWINGS

The disclosed subject matter may be understood by reference to the following description taken in conjunction with the accompanying drawings, in which like reference numerals identify like elements, and in which:

FIGS. 1A, 1B, 1C, 1D, and 1E conceptually illustrate a conventional technique for forming an n-p-n bipolar transistor;

FIG. 2 conceptually illustrates a convention CMOS transistor;

FIG. 3 illustrates a conventional integrated circuit that includes a bipolar transistor and a CMOS transistor; and

FIGS. 4A, 4B, and 4C conceptually illustrate one exemplary embodiment of a technique for forming an integrated circuit that includes a bipolar transistor and a CMOS transistor.

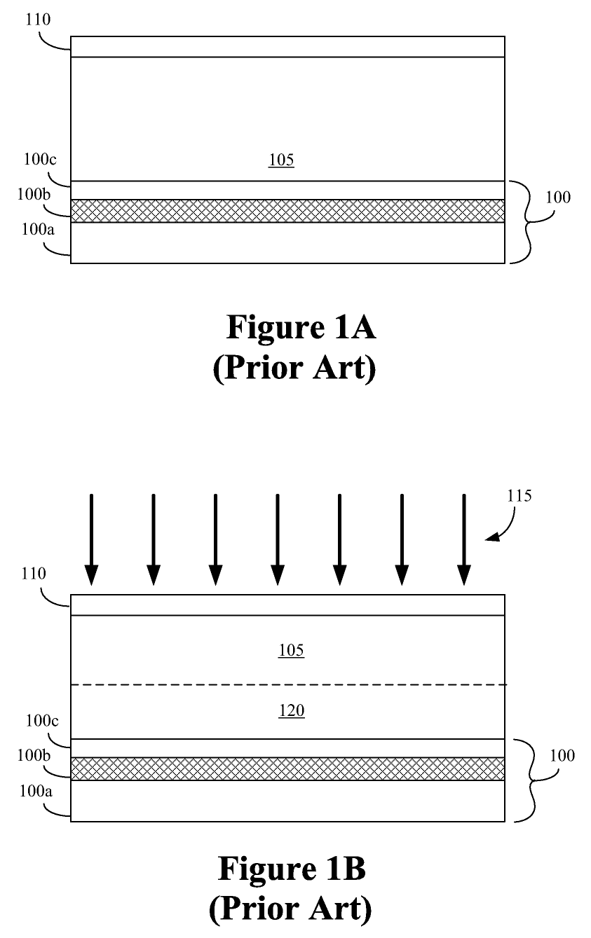

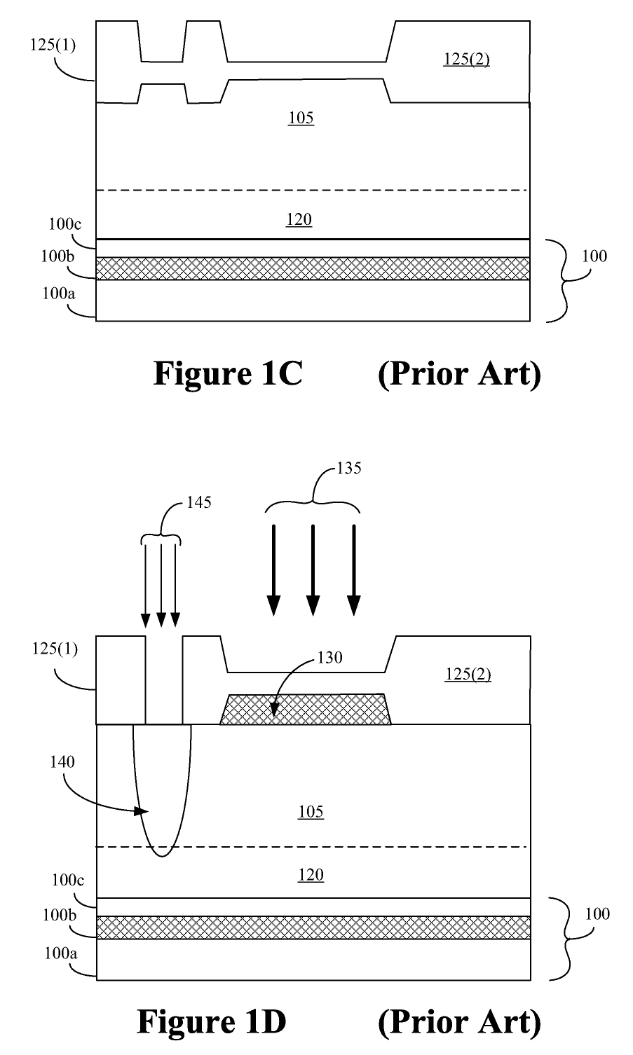

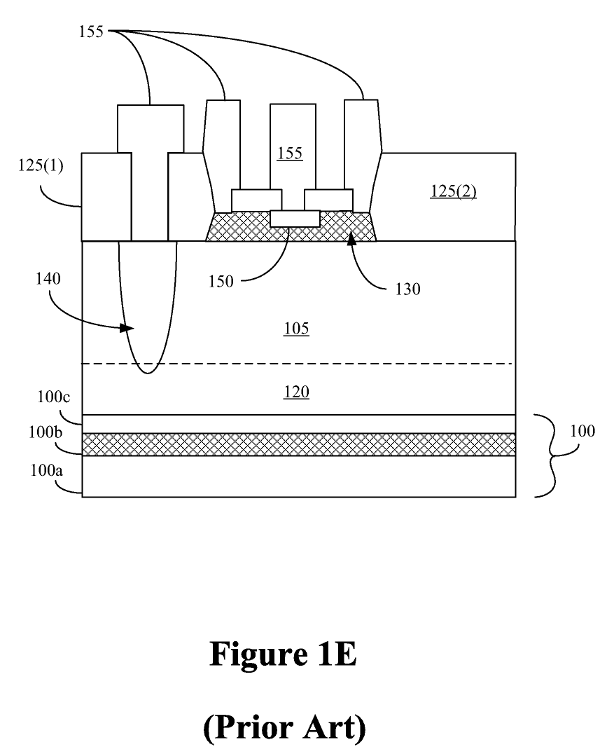

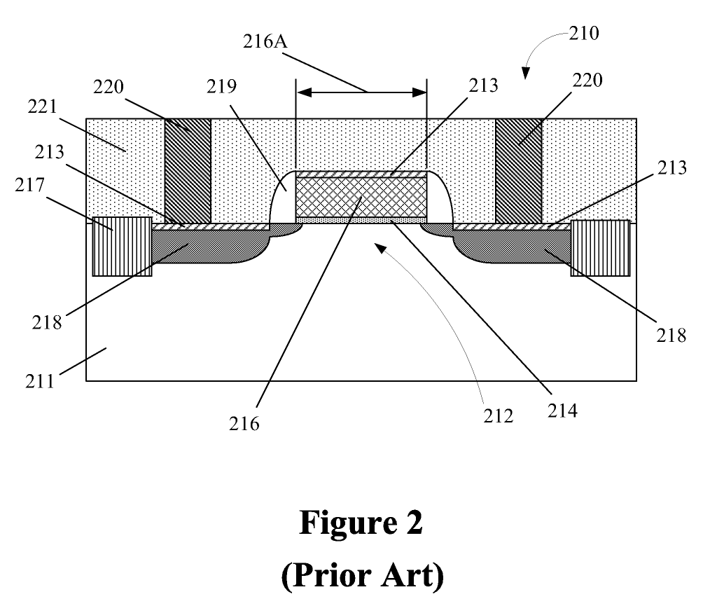

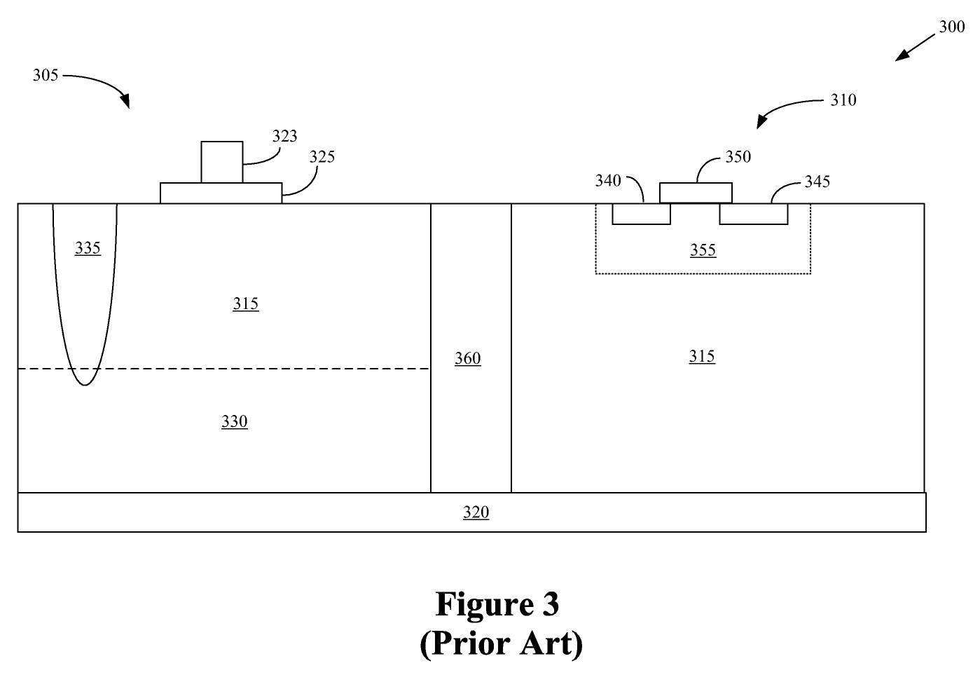

While the disclosed subject matter is susceptible to various modifications and alternative forms, specific embodiments thereof have been shown by way of example in the drawings and are herein described in detail. It should be understood, however, that the description herein of specific embodiments is not intended to limit the disclosed subject matter to the particular forms disclosed, but on the contrary, the intention is to cover all modifications, equivalents, and alternatives falling within the scope of the appended claims.

### DETAILED DESCRIPTION OF SPECIFIC EMBODIMENTS

Illustrative embodiments are described below. In the interest of clarity, not all features of an actual implementation are described in this specification. It will of course be appreciated that in the development of any such actual embodiment, numerous implementation-specific decisions should be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The disclosed subject matter will now be described with reference to the attached figures. Various structures, systems and devices are schematically depicted in the drawings for purposes of explanation only and so as to not obscure the present invention with details that are well known to those skilled in the art. Nevertheless, the attached drawings are included to describe and explain illustrative examples of the disclosed subject matter. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

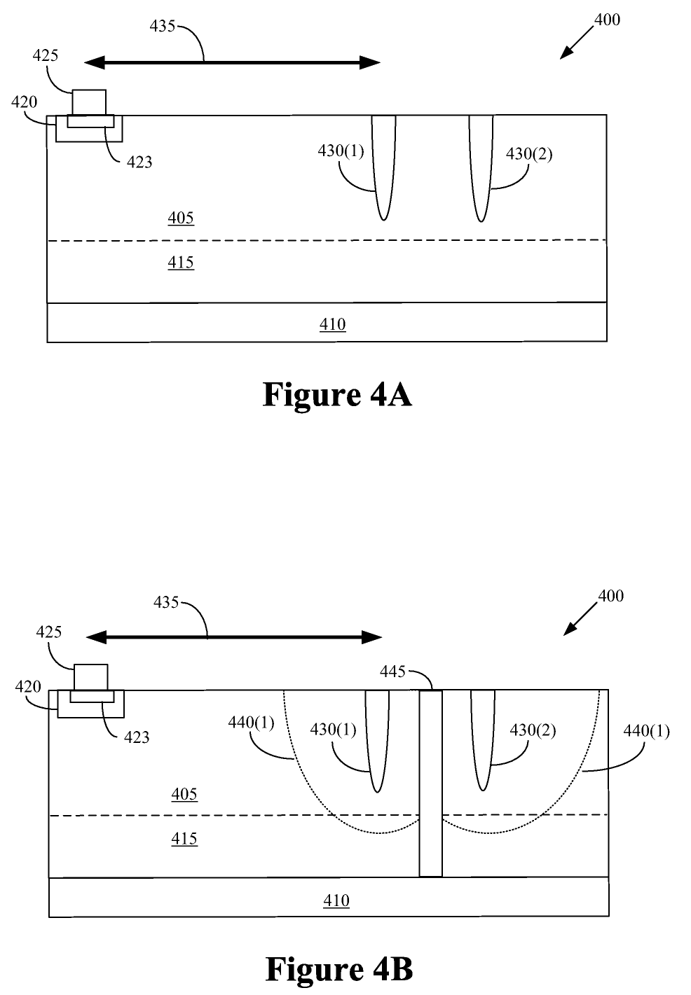

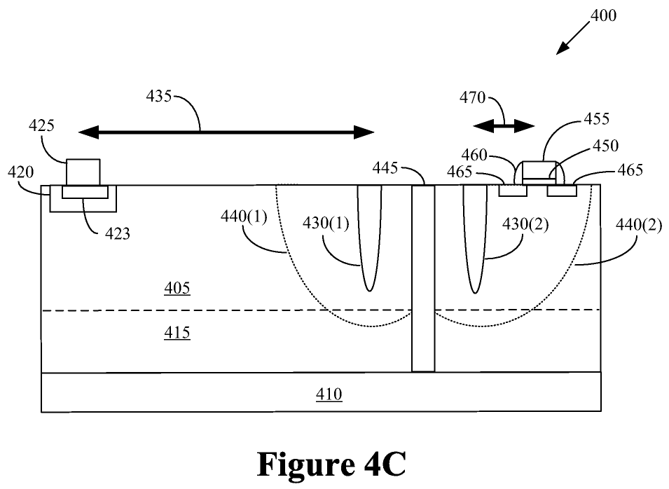

FIGS. 4A, 4B, and 4C conceptually illustrate one exemplary embodiment of a technique for forming an integrated circuit 400 that includes a bipolar transistor and a CMOS transistor. In the illustrated embodiment, the bipolar transistor is an n-p-n bipolar transistor and the CMOS transistor is a PMOS transistor. However, persons of ordinary skill in the art having benefit of the present disclosure should appreciate that the techniques described herein may alternatively be used to form an integrated circuit 400 that includes a p-n-p bipolar transistor and an NMOS transistor by reversing the types of dopants that are used. For example, the regions that are doped with an N-type dopant in an n-p-n bipolar transistor would be doped with a P-type dopant in a p-n-p bipolar transistor and vice versa. In the interest of clarity, the techniques for forming a single bipolar transistor and a single CMOS transistor have been depicted in FIGS. 4A, 4B, and 4C. However, actual integrated circuits formed using the techniques described herein are likely to include many more transistors of both types, e.g., typical high voltage circuits may include up to several hundred transistors. Persons of ordinary skill in the art having benefit of the present disclosure should appreciate that the techniques depicted in FIGS. 4A, 4B, and 4C can be used to form integrated circuits 400 having any number of bipolar transistors and/or CMOS transistors. Furthermore, persons of ordinary skill in the art having benefit of the present disclosure should appreciate that CMOS transistors are one example of a field effect transistor (FET) and that the integrated circuit 400 could include a bipolar transistor and an FET.

In FIG. 4A, the integrated circuit 400 is shown at an intermediate stage of processing. A doped layer of silicon 405 is formed above a substrate 410. In one embodiment, the substrate 410 is a silicon-on-insulator (SOI) substrate 410. However, in alternative embodiments, the substrate 410 may be any type of substrate formed using any type of material, such as a silicon substrate. In the illustrated embodiment, the layer of silicon 405 is a layer of epitaxial silicon that is deposited in an epi reactor. In this situation, the layer of epitaxial silicon 405 may be doped with an N-type dopant material, e.g., phosphorous, arsenic to a dopant concentration in the range 2×10¹⁴ to 5×10¹⁵ atoms/cm³ by introducing dopant materials into the epitaxial reactor during the process used to form the layer 405. However, the dopant material may also be introduced into the layer of silicon 405 by performing an ion implant process after the layer of silicon 405 is formed. The layer of silicon 405 is relatively thick so that the bipolar transistor can be formed in the silicon layer 405. In one illustrative embodiment, the layer of silicon 405 has a thickness that is on the order of 20-30 microns.

The distribution of dopant atoms within the layer of silicon 405 may not be uniform throughout its depth. In the illustrated embodiment, the layer 405 includes a relatively higher concentration of dopant atoms in a region near the substrate 410. The higher concentration region forms a sub-collector 415 for the bipolar transistor and the silicon layer 405 may form another portion of the collector. The relatively high concentration may be formed by performing an additional implantation step. For example, the collector 415 could be formed by performing a dopant implantation process to implant dopant species in a portion of the silicon layer 405. For an n-p-n bipolar transistor, the dopant implantation process may be used to implant an n-type dopant into the material that is later grown to form the silicon layer 405. Diffusion of the dopant species from the silicon layer 405 may then form an n-type collector 415. In one illustrative embodiment, the dopant concentration of the sub-collector 415 may be approximately 10¹⁸ to 10¹⁹ atoms/cm³. In one illustrative embodiment, the collector 415 may be located approximately 20 microns below the top surface of the doped layer 405 and extends approximately to the top surface of the substrate 400.

A base region 420 for the n-p-n bipolar transistor may be formed by implanting a p-type dopant in a portion of the silicon layer 405. In one illustrative embodiment, the dopant concentration in the base region 420 may be approximately 10¹⁶-10¹⁸ ions/cm³ and the base region 420 may extend to a depth of up to a few thousand angstroms. An emitter region including a junction 423 and a contact 425 for the n-p-n bipolar transistor is formed in and/or over the base region 420 using a material that is doped with an N-type dopant species. Illustrative dopant concentrations of the emitter regions may be in the range approximately 10¹⁹-10²⁰ atoms/cm³.

Sinkers 430(1-2) may be formed by implanting an n-type dopant species into portions of the layer 405. Techniques for forming the sinkers 430 are known in the art and in the interest of clarity only those aspects of forming the sinkers 430 that are relevant to the present subject matter will be discussed in detail herein. In the illustrated embodiment, two sinkers 430 may be formed in the silicon layer 405. However, persons of ordinary skill in the art having benefit of the present disclosure should appreciate that alternative embodiments of the integrated circuit 400 may include more sinkers 430. For example, multiple sinkers 430 may be formed such that dopant atoms that diffuse out of the sinkers 430 form overlapping extended doped regions.

In one illustrative embodiment, the sinkers 430 may be formed concurrently using the same processing steps. For example, the sinkers 430 can be formed concurrently using a patterned masking layer (not shown) and then implanting dopants through the patterned masking layer. The dopant species for the sinkers 430 may be implanted and then a heat treatment may be applied to cause the dopant species to diffuse to a depth sufficient to contact the buried layer or sub-collector 415. For example, a dopant species can be implanted using an energy that is selected to deposit the dopant atoms throughout a portion of the region between the surface of the layer 405 and the collector 415. In one embodiment, the dopant concentration in the sinkers 430 is approximately 10¹⁸-10¹⁹ atoms/cm³, although persons of ordinary skill in the art should appreciate that the dopant concentration may vary at different locations in the sinkers 430.

The sinker 430(1) may be formed at a relatively large distance 435 from the emitter 425 in the bipolar transistor. The distance 435 can be selected so that subsequent diffusion of the dopant species in the sinker 430(1) does not substantially affect the operation of the bipolar transistor. In one embodiment, the distance 435 between the emitter 425 and the sinker 430(1) is approximately 22μ. For example, the amount of lateral diffusion that occurs when forming the sinker 430(1) may be set by the amount of diffusion needed to allow the sinker 430(1) to reach the sub-collector 415. The emitter-to-sinker spacing may then be set at a value selected so that the device breakdown voltage is not limited by the spacing.

In FIG. 4B, one or more heat treatments have been applied to cause some of the dopant atoms in the sinkers 430 to diffuse outwards and downwards from the sinkers 430. Downward diffusion of the dopant atoms allows the sinkers 430 to contact the collector region 415 and the outward diffusion of the dopant atoms forms sinker wings 440. In the illustrated embodiment, the dopant concentration in the sinker wings 440 is approximately 10¹⁶ atoms/cm³, although persons of ordinary skill in the art should appreciate that the dopant concentration may vary at different locations in the sinker wings 440. Moreover, the dopant concentration in the sinker wings 440 may be varied by varying parameters (such as the temperature and the diffusion time) of the heat treatment. Diffusion of the dopant atoms out of the sinkers 430 may cause the characteristic of dopant concentration in the initial profile of the sinkers 430 to decrease slightly.

A trench 445 may also be formed between the sinkers 430 to physically and electrically isolate the sinkers 430. The trench 445 may be formed using conventional techniques such as etching and deposition. In one embodiment, the trench 445 may be formed by etching a portion of the silicon layer 405 and the collector 415 to form an opening and then depositing material within the opening. For example, one or more oxide and/or nitride trench liner layers may be deposited within the opening and a polysilicon fill may be formed within and/or above the liner layers. The trench 445 may be formed after the diffusion process has been used to form the sinker wings 440 or, alternatively, the trench 445 may be formed before applying (some or all of the) heat treatment(s) to diffuse dopant atoms out of the sinkers 430 to form the sinker wings 440. In cases where the trench 445 is formed prior to applying heat treatment, the trench 445 may stop the diffusion of the dopant species at or near the boundaries of the trench 445. Persons of ordinary skill in the art having benefit of the present disclosure should appreciate that the trench 445 is not necessary in all embodiments described herein. However, using the trench 445 may reduce an area penalty associated with the integrated circuit 400.

In FIG. 4C, a CMOS transistor has been formed within one of the sinker wings 440(2) formed by diffusion of the dopant species from the sinker 430(2). The sinker wing 440(2) therefore forms a tub for the CMOS transistor. The CMOS transistor is comprised of a gate insulation layer 450, a gate electrode 455, sidewall spacers 460, source/drain regions 465, and may also include other elements not depicted in FIG. 4C. Techniques for forming CMOS transistors within a tub are known in the art and in the interest of clarity only those aspects of forming CMOS transistors that are relevant to the present invention will be discussed herein. In the illustrated embodiment, the sinker wing 440(2) is doped with an n-type dopant and so the CMOS transistor is a PMOS transistor in which the source/drain regions 465 are formed by doping portions of the semiconductor layer 405 with a p-type dopant. However, persons of ordinary skill in the art having benefit of the present disclosure should appreciate that alternative embodiments of the integrated circuit 400 may include sinkers 430 and sinker wings 440 that are doped with a p-type dopant. In these embodiments, the CMOS transistor is an NMOS transistor that includes source/drain regions 465 that are formed by doping portions of the semiconductor layer 405 with an n-type dopant. In some cases, the integrated circuit 400 may also include both PMOS and NMOS transistors.

A separation 470 between the CMOS transistor and the sinker 430(2) can be selected so that the dopant concentration in the sinker wing 440(2) has the appropriate concentration to form a tub for the CMOS transistor. For example, the separation 470 from approximately the center of the sinker 430(2) to the approximately center of the gate 455 may be in the range from about 6 to 10 microns so that the dopant concentration in the sinker wing 440(2) is approximately 10¹⁵ to 10¹⁶ atoms/cm³. In some embodiments, the separation 470 may be selected in coordination with (or based on) the parameters of the heat treatment, such as the applied temperature and the duration of the treatment. For example, increasing the temperature and/or the duration of the heat treatment may result in increased diffusion and higher dopant concentrations at larger distances from the sinker 430(2).

Embodiments of the techniques described herein may have a number of advantages over conventional practice. For example, conventional techniques for forming bipolar transistors and CMOS transistors in the same integrated circuit include additional processing steps for forming tubs for the CMOS transistors. The additional processing steps may include depositing and/or patterning masking layers, implanting a dopant species through the masking layer, and/or removing the masking layer. In contrast, the techniques described herein form the tub using the same processes that are used to form sinkers for the bipolar transistor, thereby reducing the number of processing steps that are required to form the bipolar transistors and CMOS transistors.

The particular embodiments disclosed above are illustrative only, as the disclosed subject matter may be modified and practiced in different but equivalent manners apparent to those skilled in the art having the benefit of the teachings herein. Furthermore, no limitations are intended to the details of construction or design herein shown, other than as described in the claims below. It is therefore evident that the particular embodiments disclosed above may be altered or modified and all such variations are considered within the scope of the disclosed subject matter. Accordingly, the protection sought herein is as set forth in the claims below.

What is claimed:

1. A method of fabricating an integrated circuit comprising at least one bipolar transistor and at least one field effect transistor, comprising:
implanting a dopant species of a first type in a semiconductor layer that is doped with a dopant of a second type to form at least one sinker that contacts at least a portion of a collector of said at least one bipolar transistor, wherein the second type of doped is opposite to the first type of dopant;
applying heat to cause the dopant species to diffuse outwards to form at least one doped extension of said at least one sinker; and
forming said at least one field effect transistor in said at least one doped extension.

2. The method of claim 1, comprising forming at least one trench between said at least one bipolar transistor and said at least one field effect transistor.

3. The method of claim 1, comprising forming more than one field effect transistor in said at least one doped extension.

4. The method of claim 1, comprising forming at least two sinkers and applying heat to form at least two extended doped regions corresponding to said at least two extended doped regions, said at least two extended doped regions overlapping partially to form at least one dual extended doped region.

5. The method of claim 4, comprising forming said at least one field effect transistor in said at least one dual extended doped region.

6. The method of claim 1, comprising forming a plurality of sinkers and doped extensions in portions of the semiconductor layer corresponding to a plurality of bipolar transistors and forming a plurality of field effect transistors in the plurality of doped extensions.

7. The method of claim 6, comprising forming a plurality of trenches between the pluralities of bipolar transistors and field effect transistors.

8. The method of claim 1, wherein forming said at least one field effect transistor comprises forming at least one metal oxide semiconductor (MOS) transistor.

9. The method of claim 8, wherein forming said at least one bipolar transistor comprises forming at least one n-p-n bipolar transistor and wherein forming said at least one metal oxide semiconductor transistor comprises forming at least one PMOS transistor.

10. The method of claim 8, wherein forming said at least one bipolar transistor comprises forming at least one p-n-p bipolar transistor and wherein forming said at least one metal oxide semiconductor transistor comprises forming at least one NMOS transistor.
